(19) United States
(12) Patent Application Publication
(10) Pub. No.: US 2025/0243581 A1
(43) Pub. Date: Jul. 31, 2025

(54) FILM FORMING METHOD AND FILM FORMING APPARATUS

(71) Applicant: Tokyo Electron Limited, Tokyo (JP)

(72) Inventors: Yumiko KAWANO, Nirasaki City (JP); Shuji AZUMO, Nirasaki City (JP)

(21) Appl. No.: 19/086,206

(22) Filed: Mar. 21, 2025

Related U.S. Application Data
(63) Continuation of application No. PCT/JP2023/033371, filed on Sep. 13, 2023.

(30) Foreign Application Priority Data
Sep. 27, 2022 (JP) 2022-153617

(51) Int. Cl. C23C 16/455; C23C 16/44; C23C 16/52; C23C 16/56

(52) U.S. Cl. CPC C23C 16/45523; C23C 16/4405; C23C 16/52; C23C 16/56

(57) ABSTRACT

A film forming method includes preparing a substrate having a first film and a second film on different regions of a surface thereof, the second film being formed of a material different from that of the first film, and forming a self-assembled monolayer on a surface of the second film in a selective manner relative to a surface of the first film by supplying an organic compound gas and an oxygen-containing gas that does not contain an OH group into a processing container accommodating the substrate.

### CROSS-REFERENCE TO RELATED APPLICATION

This application is a bypass continuation application of International Application No. PCT/JP2023/033371 having an international filing date of Sep. 13, 2023 and designating the United States, the international application being based upon and claiming the benefit of priority from Japanese Patent Application No. 2022-153617, filed on Sep. 27, 2022, the entire contents of which are incorporated herein by reference.

### TECHNICAL FIELD

The present disclosure relates to a film forming method and a film forming apparatus.

### BACKGROUND

Patent Document 1 describes a film forming method in which a self-assembled monolayer (SAM) is used to inhibit the formation of a target film on a portion of a substrate surface while forming the target film on another portion of the substrate surface. The film forming method described in Patent Document 1 includes reducing a natural oxide film formed on a surface of a first material layer and oxidizing the surface of the first material layer, before forming the SAM on the surface of the first material layer.

### PRIOR ART DOCUMENT

### Patent Document

Patent Document 1: Japanese laid-open publication No. 2021-57563

### SUMMARY

According to one embodiment of the present disclosure, there is provided a film forming method including preparing a substrate having a first film and a second film on different regions of a surface of the substrate, the second film being formed of a material different from that of the first film, and forming a self-assembled monolayer on a surface of the second film in a selective manner relative to a surface of the first film by supplying an organic compound gas and an oxygen-containing gas that does not contain an OH group into a processing container accommodating the substrate.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a flowchart illustrating a film forming method according to one embodiment.

FIG. 2A is a diagram illustrating step S1 according to one embodiment.

FIG. 2B is a diagram illustrating step S2 according to one embodiment.

FIG. 2C is a diagram illustrating step S3 according to one embodiment.

FIG. 2D is a diagram illustrating step S4 according to one embodiment.

FIG. 2E is a diagram illustrating step S5 according to one embodiment.

FIG. 2F is a diagram illustrating step S6 according to one embodiment.

FIG. 3 is a flowchart illustrating one example of a subroutine of step S4.

FIG. 4 is a flowchart illustrating one example of a subroutine of step S5.

FIG. 5 is a flowchart illustrating one example of a subroutine of step S6.

FIG. 6A is a diagram illustrating step S1 according to a first modification.

FIG. 6B is a diagram illustrating step S2 according to the first modification.

FIG. 6C is a diagram illustrating step S3 according to the first modification.

FIG. 6D is a diagram illustrating step S4 according to the first modification.

FIG. 6E is a diagram illustrating step S5 according to the first modification.

FIG. 6F is a diagram illustrating step S6 according to the first modification.

FIG. 7A is a diagram illustrating step S1 according to a second modification.

FIG. 7B is a diagram illustrating step S2 according to the second modification.

FIG. 7C is a diagram illustrating step S3 according to the second modification.

FIG. 7D is a diagram illustrating step S4 according to the second modification.

FIG. 7E is a diagram illustrating step S5 according to the second modification.

FIG. 7F is a diagram illustrating step S6 according to the second modification.

FIG. 8 is a plan view illustrating a film forming apparatus according to one embodiment.

FIG. 9 is a cross-sectional view illustrating one example of a first processing section of FIG. 8.

FIG. 10 is a diagram illustrating the XPS spectra of a substrate surface obtained in Examples 2-1 to 2-3.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Hereinafter, embodiments of the present disclosure will be described with reference to the accompanying drawings. In addition, in each drawing, the same reference numerals will be given to the same or corresponding components, and descriptions thereof may be omitted.

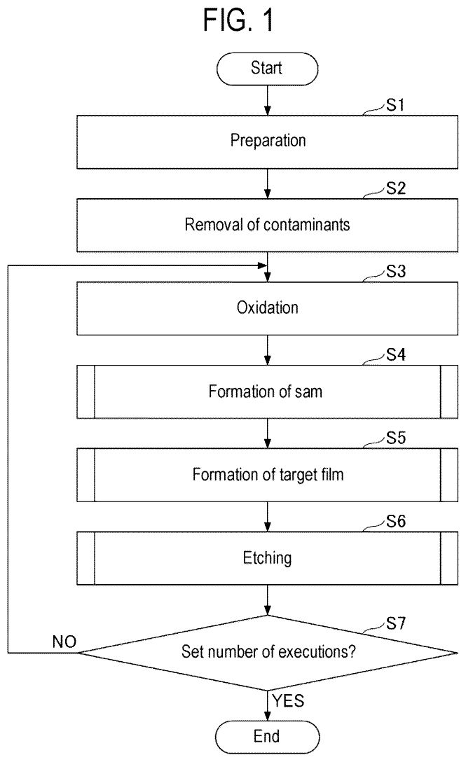

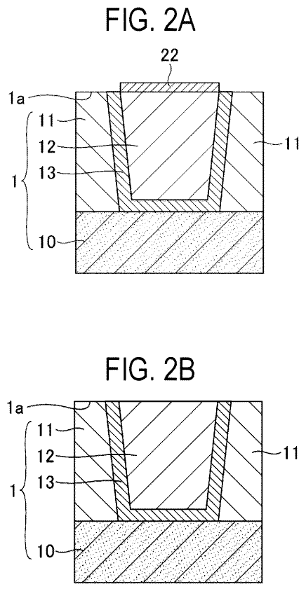

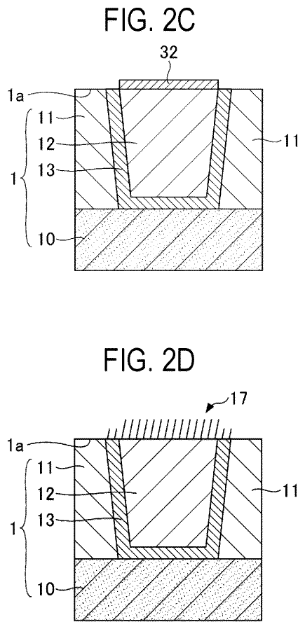

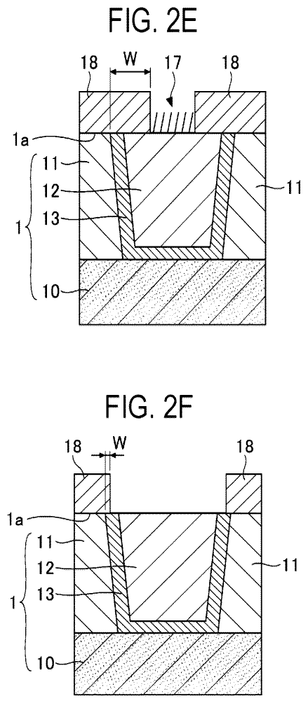

A film forming method according to one embodiment will be described with reference to FIGS. 1 and 2A to 2F. The film forming method includes steps S1 to S7 illustrated in FIG. 1, for example. In addition, the film forming method may include at least steps S1 and S4 and, for example, may omit steps S2 and S3 and S5 to S7. Further, the film forming method may include steps other than steps S1 to S7 illustrated in FIG. 1.

Step S1 in FIG. 1 includes preparing a substrate 1, as illustrated in FIG. 2A. The substrate 1 includes a base substrate 10. The base substrate 10 is, for example, a silicon wafer, compound semiconductor wafer, or glass substrate. The substrate 1 includes an insulating film 11 and a conductive film 12 in different regions of a substrate surface 1a. The substrate surface 1a is, for example, an upper surface of the substrate 1. The insulating film 11 and conductive film 12 are formed on the base substrate 10. Another functional film may be formed between the base substrate 10 and the insulating film 11 or between the base substrate 10 and the conductive film 12. The insulating film 11 is an example of a first film, and the conductive film 12 is an example of a second film. In addition, the materials of the first film and second film are not particularly limited.

The insulating film 11 is, for example, an interlayer insulating film. The interlayer insulating film may be a low-dielectric (low-k) constant film. The insulating film 11 is not particularly limited but is, for example, an SiO film, SiN film, SiOC film, SiON film, or SiOCN film. Here, the SiO film refers to a film containing silicon (Si) and oxygen (O). The atomic ratio of Si to O in the SiO film is typically 1:2 but is not limited to 1:2. The same applies to the SiN film, SiOC film, SiON film, and SiOCN film, which refer to films containing respective elements, and are not limited to stoichiometric ratios. The insulating film 11 has a recess in the substrate surface 1a. The recess is a trench, contact hole, or via hole.

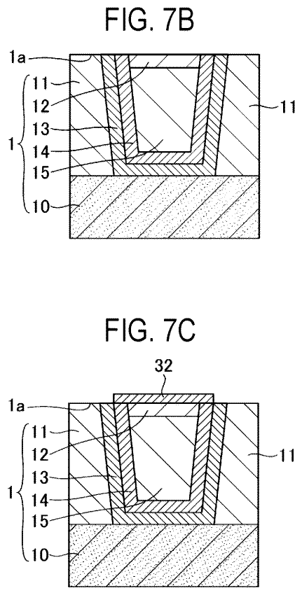

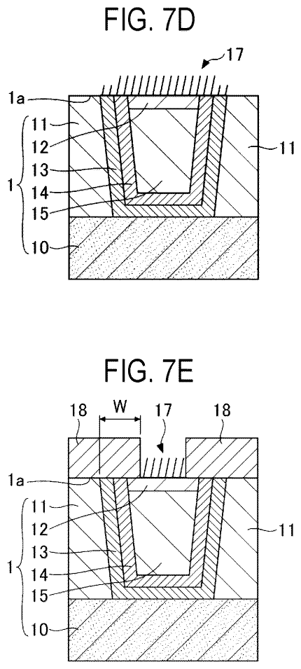

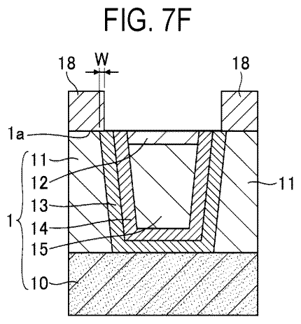

The conductive film 12 fills the recess of the insulating film 11, for example. The conductive film 12 is, for example, a metal film. Examples of the metal film include a Cu film, Co film, Ru film, and W film. In addition, the conductive film 12 may be a cap film. Specifically, as illustrated in FIG. 7A, a second conductive film 15 may be embedded in the recess of the insulating film 11, and the conductive film 12 may cover the second conductive film 15. The second conductive film 15 is formed of a metal different from that of the conductive film 12.

The substrate 1 may further include a third film on the substrate surface 1a. The third film is, for example, a barrier film 13. The barrier film 13 is formed between the insulating film 11 and the conductive film 12 to prevent metal diffusion from the conductive film 12 to the insulating film 11. The barrier film 13 is not particularly limited but may be, for example, a TaN film or TiN film. Here, the TaN film refers to a film containing tantalum (Ta) and nitrogen (N). The atomic ratio of Ta to N in the TaN film is typically 1:1 but is not limited to 1:1. The same applies to the TiN film, which refers to a film containing respective elements and is not limited to stoichiometric ratios.

Table 1 summarizes specific examples of the insulating film 11, the conductive film 12, and the barrier film 13.

TABLE 1

| Insulating film | Conductive film | Barrier film |
|---|---|---|
| SiO film | Cu film | TaN film |
| SiN film | Co film | TiN film |
| SiOC film | Ru film | |
| SiON film | W film | |
| SiOCN film | | |

In addition, combinations of the insulating film 11, the conductive film 12, and the barrier film 13 are not particularly limited.

As illustrated in FIG. 2A, contaminants 22 may be present on a surface of the conductive film 12. The contaminants 22 include, for example, at least one of a metal oxide and an organic substance. The metal oxide is an oxide formed by the reaction between the conductive film 12 and the atmosphere, which is a so-called natural oxide film. The organic substance adheres during the processing of the substrate 1. Although not illustrated, contaminants such as organic substances may also be present on surfaces of the insulating film 11 and barrier film 13.

Step S2 in FIG. 1 includes removing the contaminants 22, as illustrated in FIG. 2B. This exposes the surface of the conductive film 12. For example, step S2 includes supplying a cleaning gas to the substrate surface 1a. The cleaning gas may be plasmarized to improve the removal efficiency of the contaminants 22. The cleaning gas includes, for example, a reducing gas such as a hydrogen gas (H₂ gas). The reducing gas removes oxides such as a natural oxide film. The cleaning gas may also include a nitrogen gas (N₂ gas), in addition to the reducing gas, in order to remove organic substances.

An example of a processing condition for step S2 is described below.
H₂ gas flow rate: 50 sccm to 5000 sccm
N₂ gas flow rate: 50 sccm to 10000 sccm
Ar gas flow rate: 20 sccm to 10000 sccm
Proportion of H₂ gas in cleaning gas: 10 vol % to 60 vol %
Proportion of N₂ gas in cleaning gas: 10 vol % to 80 vol %
Power supply frequency for plasma generation: 10 MHz to 40 MHz
Power for plasma generation: 100 W to 400 W
Processing time: 5 sec to 120 sec
Processing temperature (substrate temperature): 80 to 350 degrees C.
Processing pressure: 50 Pa to 2000 Pa

Step S3 in FIG. 1 includes forming an oxide film 32 by oxidizing the surface of the conductive film 12, as illustrated in FIG. 2C. For example, step S3 includes supplying an oxygen-containing gas to the substrate surface 1a to form the oxide film 32. The oxygen-containing gas includes a gas that does not contain OH-groups, for example, at least one selected from O₂ gas, O₃ gas, NO gas, NO₂ gas, and N₂O gas. In addition, the surface oxidation of the conductive film 12 may be performed as a wet process instead of a dry process.

Since the contaminants 22 have been completely removed before step S3, the oxide film 32 having a desired film thickness and desired film quality is obtained in step S3. The film quality includes the surface state of the film. Unlike a natural oxide film, the oxide film 32 allows control of the film thickness and film quality based on a precursor gas and film formation condition. By forming the oxide film 32 having a desired film thickness and desired film quality, a dense self-assembled monolayer (SAM) may be formed on the surface of the conductive film 12 in step S4 to be described later.

An example of a processing condition for step S3 is described below.
O₂ gas flow rate: 50 sccm to 4000 sccm
Processing time: 1 sec to 300 sec
Processing temperature: 80 to 350 degrees C.
Processing pressure: 50 Pa to 2000 Pa

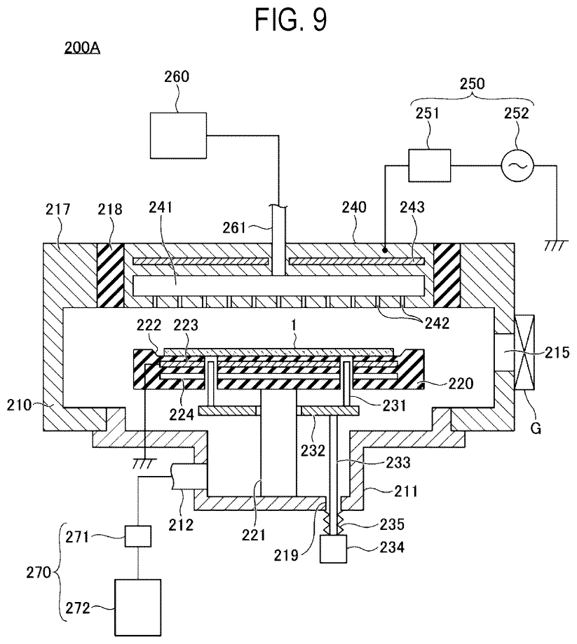

Step S4 in FIG. 1 includes forming a SAM 17 on the surface of the conductive film 12 in a selective manner relative to the surface of the insulating film 11, as illustrated in FIG. 2D, by supplying an organic compound gas and oxygen-containing gas into a processing container (e.g., processing container 210 in FIG. 9) accommodating the substrate 1. The organic compound gas is a precursor for the SAM 17. The organic compound gas is not particularly limited but is, for example, a thiol-based compound.

The thiol-based compound has a hydrogenated sulfur group as a head group and is represented by the general formula “R—SH”. R is, for example, a hydrocarbon group, or a hydrocarbon group in which at least part of hydrogen is replaced with fluorine. Specific examples of the thiol-based compound include CF₃(CF₂)₅CH₂CH₂SH(1H, 1H, 2H, 2H-perfluorooctanethiol: PFOT) and CF₃(CF₂)₇CH₂CH₂SH(1H, 1H, 2H, 2H-perfluorodecanethiol: PFDT).

The thiol-based compound is more likely to be chemically adsorbed onto the surface of the conductive film 12 than onto the surface of the insulating film 11. Therefore, the SAM 17 is formed on the surface of the conductive film 12 in a selective manner relative to the surface of the insulating film 11. When the oxide film 32 is formed before the formation of the SAM 17, the density of the SAM 17 may be enhanced compared to when the oxide film 32 is not formed, and the blocking performance of the SAM 17 may be enhanced in step S5 to be described later. Since the thiol-based compound is chemically adsorbed while reducing the oxide film 32, the oxide film 32 may not remain after step S4 (see FIGS. 2D, 6D and 7D).

The thiol-based compound is also more likely to be chemically adsorbed onto the barrier film 13 than onto the insulating film 11. Therefore, the SAM 17 is selectively formed on the surface of the barrier film 13. In addition, the thiol-based compound is more likely to be chemically adsorbed onto the surface of the conductive film 12 than onto the surface of the barrier film 13, so that the SAM 17 is more easily formed on the surface of the conductive film 12 than on the surface of the barrier film 13.

The precursor for the SAM 17 is not limited to the thiol-based compound. For example, the precursor for the SAM 17 may be a phosphonic acid-based compound. The phosphonic acid-based compound is represented by the general formula “R—P(═O)(OH)₂”. R is, for example, a hydrocarbon group, or a hydrocarbon group in which at least part of hydrogen is replaced with fluorine.

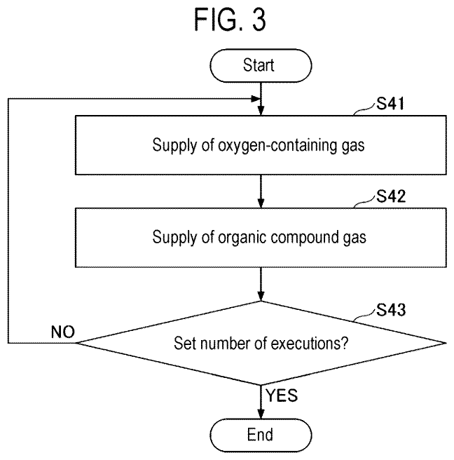

Step S4 in FIG. 1 includes steps S41 to S43 illustrated in FIG. 3, for example. Step S41 includes supplying an oxygen-containing gas that does not contain OH-groups into the processing container accommodating the substrate 1. Step S42 includes supplying an organic compound gas into the processing container. In addition, the order of steps S41 and S42 may be reversed.

Due to alternately performing step S41 and step S42, the organic compound gas may be stored in an external tank during the supply of oxygen-containing gas into the processing container in step S41, so that the organic compound gas may be supplied from the external tank to the processing container in step S42. This is effective when an organic compound has a low vapor pressure and it takes time to secure the amount of organic compound gas.

Step S43 includes checking whether steps S41 and S42 have been performed a set number of executions. If the number of executions has not reached the set number (“NO” in step S43), the density of the SAM 17 is insufficient, so that steps S41 and S42 are performed again. On the other hand, if the number of executions has reached the set number (“YES” in step S43), the density of the SAM 17 is sufficient, so that the process for this cycle is terminated.

In the present embodiment, as illustrated in FIG. 3, the supply of oxygen-containing gas and the supply of organic compound gas are performed sequentially, not simultaneously, but they may also be performed simultaneously. In either case, the supply of oxygen-containing gas allows for the oxidation of the conductive film 12. The oxidation of the conductive film 12 may also occur in a distributed manner between steps S3 and S4.

According to the present embodiment, the oxidation of the conductive film 12 may be distributed between steps S3 and S4. This distribution of the oxidation of the conductive film 12 may also be achieved by repeating steps S41 and S42 multiple times. The surface roughness of the conductive film 12 due to oxidation may be minimized compared to a case where the oxide film 32 having a thickness sufficient to form the dense SAM 17 is formed all at once only in step S3. Thus, both the minimization of the surface roughness of the substrate surface and the enhancement of the density of the SAM 17 may be achieved simultaneously.

The oxygen-containing gas used in step S4, like the oxygen-containing gas used in step S3, includes a gas that does not contain OH-groups, for example, at least one selected from O₂ gas, O₃ gas, NO gas, NO₂ gas, and N₂O gas. If a gas containing OH-groups such as H₂O is used as the oxygen-containing gas, it becomes difficult to form a uniform oxide film on the surface of the conductive film 12 with controlled properties. The resulting oxide film becomes too thin or uneven. Furthermore, H₂O is likely to remain on the inner wall surface of the processing container or on the substrate surface 1a, and depending on the type of the SAM 17, H₂O inhibits the adsorption of the SAM 17 onto the conductive film 12.

The set number of executions for step S43 may be one but may be multiple times. By repeating the supply of oxygen-containing gas and the supply of organic compound gas sequentially, the oxidation of the conductive film 12 may be gradually promoted, and the surface roughness of the conductive film 12 due to oxidation may be further minimized. The set number of executions for step S43 is, for example, between 2 and 15.

An example of a processing condition for step S4 is described below.

### Step S41

O₂ gas flow rate: 100 sccm to 4000 sccm
Processing time: 3 sec to 120 sec

### Step S42

PFOT gas flow rate: 50 sccm to 200 sccm
Processing time: 3 sec to 120 sec
Processing condition common to steps S41 and S42
Processing temperature: 80 to 250 degrees C.
Processing pressure: 50 Pa to 4000 Pa

Step S5 in FIG. 1 includes forming a target film 18 on the surface of the insulating film 11 while inhibiting the formation of the target film 18 on the surface of the conductive film 12 using the SAM 17, as illustrated in FIG. 2E. The target film 18 is, for example, an insulating film, and is formed on the insulating film 11. According to the present embodiment, the density of the SAM 17 is high, so the blocking performance of the SAM 17 is good.

As described above, the SAM 17 is formed not only on the surface of the conductive film 12 but also on the surface of the barrier film 13. In this case, step S5 may include forming the target film 18 on the surface of the insulating film 11 while inhibiting the formation of the target film 18 on the surface of the conductive film 12 and the surface of the barrier film 13 using the SAM 17. In addition, since the blocking performance of the SAM 17 is not perfect, the target film 18 may protrude laterally beyond the surface of the insulating film 11, covering the surface of the barrier film 13.

The target film 18 is not particularly limited but is, for example, an AlO film, SiO film, SiN film, ZrO film, or HfO film. Here, the AlO film refers to a film containing aluminum (Al) and oxygen (O). The atomic ratio of Al to O in the AlO film is typically 2:3 but is not limited to 2:3. The same applies to the SiO film, SiN film, ZrO film, and HfO film, which refer to films containing respective elements, and are not limited to stoichiometric ratios. The target film 18 is formed, for example, by a chemical vapor deposition (CVD) method or atomic layer deposition (ALD) method.

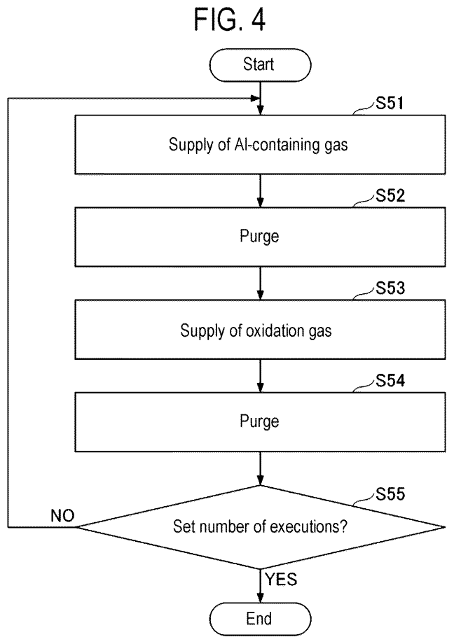

When forming an AlO film by an ALD method, an Al-containing gas such as trimethylaluminum (TMA) gas and an oxidation gas such as water vapor (H₂O gas) are alternately supplied to the substrate surface 1a. The method for forming the AlO film includes steps S51 to S55 illustrated in FIG. 4, for example.

Step S51 includes supplying an Al-containing gas to the substrate surface 1a. Step S52 includes supplying an inert gas such as Ar gas to the substrate surface 1a to purge any excess Al-containing gas that has not been adsorbed onto the substrate surface 1a. Step S53 includes supplying an oxidation gas to the substrate surface 1a. Step S54 includes supplying an inert gas such as Ar gas to the substrate surface 1a to purge any excess oxidation gas that has not been adsorbed onto the substrate surface 1a. In addition, the order of steps S51 and S53 may be reversed.

Step S55 includes checking whether steps S51 to S54 have been performed a set number of executions. If the number of executions has not reached the set number (“NO” in step S55), steps S51 to S54 are performed again. On the other hand, if the number of executions has reached the set number (“YES” in step S55), the thickness of the AlO film has reached a target film thickness, so that the process for this cycle is terminated. The set number of executions for step S55 depends on the target film thickness of the AlO film and is, for example, between 10 and 100.

An example of a processing condition for step S5 is described below.

step S51
TMA gas flow rate: 10 sccm to 100 sccm
Processing time: 0.05 sec to 10 sec

### Step S52

Ar gas flow rate: 1000 sccm to 8000 sccm
Processing time: 0.5 sec to 10 sec

### Step S53

H₂O gas flow rate: 50 sccm to 500 sccm
Processing time: 0.1 sec to 10 sec

### Step S54

Ar gas flow rate: 1000 sccm to 8000 sccm
Processing time: 0.5 sec to 10 sec
Processing condition common to steps S51 to S54
Processing temperature: 100 to 350 degrees C.
Processing pressure: 133 Pa to 1200 Pa

By the way, as illustrated in FIG. 2E, the SAM 17 inhibits the formation of the target film 18, but the blocking performance of the SAM 17 is not perfect, causing the target film 18 to protrude laterally beyond the surface of the insulating film 11. The width W of a protruding portion, i.e., unnecessary portion of the target film 18, is, for example, approximately 2 nm to 10 nm.

Step S6 in FIG. 1 includes etching the unnecessary portion of the target film 18, as illustrated in FIG. 2F. This may enlarge an opening of the target film 18, thereby reducing the wiring resistance of the substrate 1.

If the organic compound that is the precursor for the SAM 17 contains fluorine, step S6 includes supplying an H₂O-containing gas to the substrate surface 1a. The reaction between the H₂O-containing gas and the SAM 17 generates hydrofluoric acid. The generated hydrofluoric acid may etch the unnecessary portion of the target film 18, as illustrated in FIG. 2F. Etching products are volatile, vaporize, and are exhausted. As described above, the target film 18 is, for example, an AlO film, SiO film, SiN film, ZrO film, or HfO film. All of these films may be etched with hydrofluoric acid.

As described above, hydrofluoric acid is generated through the reaction between the H₂O-containing gas and the SAM 17. Thus, hydrofluoric acid is only generated near the SAM 17. Therefore, the unnecessary portion of the target film 18 is etched, while a necessary portion (portion deposited on the surface of the insulating film 11) is not etched. This allows for the selective removal of the unnecessary portion of the target film 18. According to the present embodiment, the density of the SAM 17 may be enhanced by performing the supply of oxygen-containing gas and the supply of organic compound gas in step S4, making it easier to generate hydrofluoric acid.

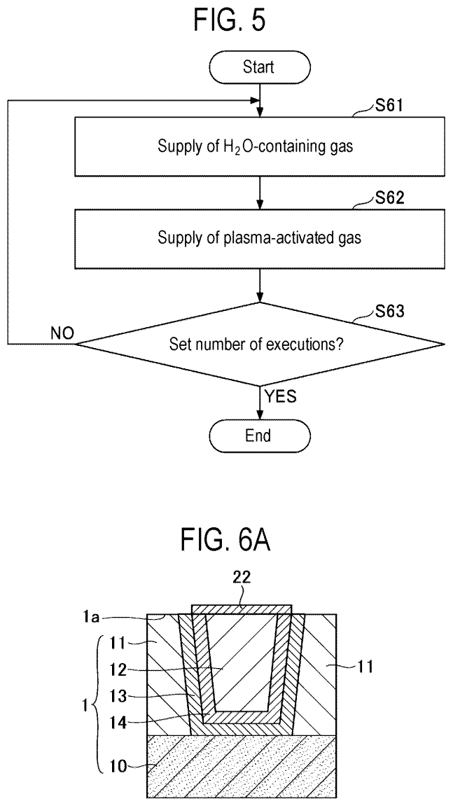

Step S6 in FIG. 1 includes steps S61 to S63 illustrated in FIG. 5, for example. Step S61 includes supplying an H₂O-containing gas to the substrate surface 1a. The H₂O-containing gas may include only an H₂O gas, or may include both an H₂O gas and a carrier gas.

Step S62 includes supplying a plasmarized gas to the substrate surface 1a. The plasmarized gas is, for example, at least one selected from an H₂ gas, Ar gas, N₂ gas, and NH₃ gas that has been plasmarized. By supplying the plasmarized gas, the SAM 17 may be decomposed, which may promote the generation of hydrofluoric acid. To prevent the oxidation of the exposed conductive film 12 or barrier film 13 after the decomposition of SAM 17, it is desirable for the plasmarized gas to be a reducing gas or inert gas. In addition, the order of steps S61 and S62 may be reversed.

Step S63 includes checking whether steps S61 and S62 have been performed a set number of executions. If the number of executions has not reached the set number (“NO” in step S63), steps S61 and S62 are performed again. On the other hand, if the number of executions has reached the set number (“YES” in step 63), the process for this cycle is terminated.

In FIG. 5, the H₂O-containing gas and plasmarized gas are supplied sequentially, not simultaneously, but may also be supplied simultaneously. In either case, by supplying the plasmarized gas, the SAM 17 may be decomposed, which may promote the generation of hydrofluoric acid. However, by supplying the H₂O-containing gas and plasmarized gas sequentially, the plasma activation of the H₂O-containing gas may be prevented and the generation of oxygen plasma may be prevented, which may prevent the oxidation of the substrate surface 1a.

The set number of executions for step S63 may be one but may be multiple times. By dividing the supply of plasmarized gas into multiple stages, the decomposition of the SAM 17 may gradually progress, allowing hydrofluoric acid to be generated over an extended period, which may reduce the width W of the unnecessary portion. As a result, the wiring resistance of the substrate 1 may be reduced. The set number of executions for step S63 is, for example, between 1 and 50.

An example of a processing condition for step S6 is described below.

### Step S61

H₂O gas flow rate: 10 sccm to 500 sccm
Processing time: 0.1 sec to 120 sec

### Step S62

H₂ gas flow rate: 200 sccm to 3000 sccm
Ar gas flow rate: 100 sccm to 6000 sccm
Proportion of H₂ gas in mixed gas of H₂ gas and Ar gas: 20 vol % to 90 vol %
Power supply frequency for plasma generation: 10 MHz to 60 MHz
Power for plasma generation: 50 W to 600 W
Processing time: 2 sec to 120 sec
Processing condition common to steps S61 and S62
Processing temperature: 100 to 350 degrees C.
Processing pressure: 50 Pa to 1200 Pa

Step S6 may include decomposing and removing the SAM 17, as illustrated in FIG. 2F. After step S6, the SAM 17 may not remain on the substrate surface 1a.

In addition, although not illustrated, step S6 may include forming and replenishing the SAM 17 on the surface of the conductive film 12 in the course of performing the step. Replenishing the SAM 17 allows hydrofluoric acid to be generated over a prolonged period, thereby narrowing the width W of the unnecessary portion of the target film 18 and reducing the wiring resistance of the substrate 1. In this case, supplying an O₂ gas or similar gases before the formation of the SAM 17 enables the formation of a greater amount of the SAM 17.

Step S7 in FIG. 1 includes checking whether steps S3 to S6 have been performed a set number of executions. If the number of executions has not reached the set number (“NO” in step S7), steps S3 to S6 are performed again. On the other hand, if the number of executions has reached the set number (“YES” in step S7), the thickness of the AlO film has reached a final target film thickness, so that the process for this cycle is terminated. The set number of executions for step S7 depends on the final target film thickness of the AlO film.

The set number of executions for step S7 may be one, but may be multiple times. By dividing the formation of the AlO film into multiple stages, the width W of the unnecessary portion of the target film 18 may be reduced in each step S5, compared to performing the formation of the AlO film once. The narrower the width W, the easier it becomes to remove the unnecessary portion. Thus, dividing the formation of the AlO film into multiple stages allows for a narrower final width W of the unnecessary portion of the target film 18 compared to performing the formation of the AlO film once, ultimately reducing the wiring resistance of the substrate 1.

As illustrated in FIG. 1, step S3 may be performed after the n^{th} step S6 (n being a natural number equal to or greater than 1) and before the n+1^{th} step S4. The re-execution of step S3 is effective when supplying the plasmarized H₂ gas to the substrate surface 1a during step S6. This is because, during step S6, the surface of the conductive film 12 is reduced similar to step S2. By performing step S3 after step S6, the surface of the conductive film 12 may be appropriately oxidized. As a result, during the subsequent execution of step S4, the dense SAM 17 may be formed on the surface of the conductive film 12.

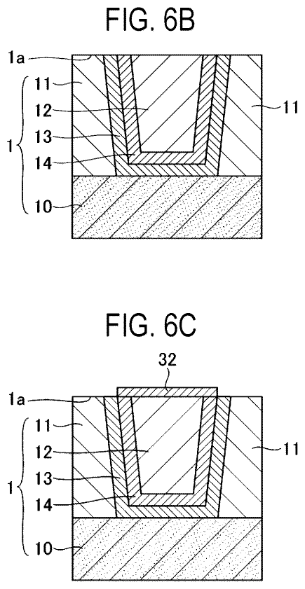

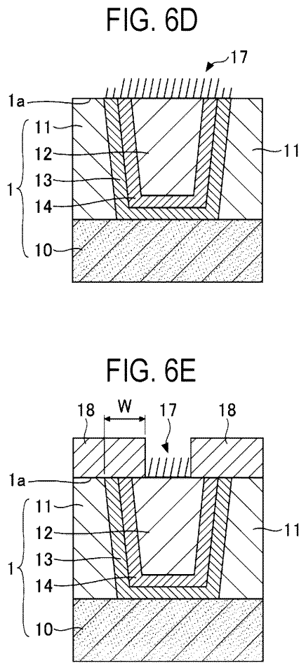

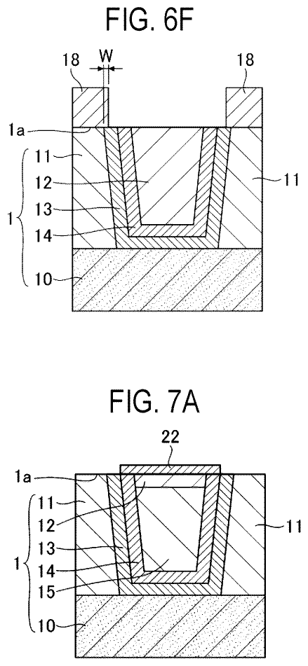

Next, the processing of the substrate 1 according to a first modification will be described with reference to FIGS. 6A to 6F. As illustrated in FIG. 6A, the substrate 1 of this modification includes a liner film 14 on the substrate surface 1a, in addition to the insulating film 11, conductive film 12, and barrier film 13. The liner film 14 is formed between the conductive film 12 and the barrier film 13. The liner film 14 is formed on the barrier film 13 and supports the formation of the conductive film 12. The conductive film 12 is formed on the liner film 14. The liner film 14 is not particularly limited but is, for example, a Co film or Ru film.

Table 2 summarizes specific examples of the insulating film 11, conductive film 12, barrier film 13, and liner film 14.

TABLE 2

| Insulating film | Conductive film | Barrier film | Liner film |
|---|---|---|---|
| SiO film | Cu film | TaN film | Co film |
| SiN film | | TiN film | Ru film |
| SiOC film | | | |
| SiON film | | | |
| SiOCN film | | | |

In addition, combinations of the insulating film 11, conductive film 12, barrier film 13 and liner film 14 are not particularly limited.

As illustrated in FIG. 6A, the contaminants 22 may be present on a surface of the liner film 14, similar to on the surface of the conductive film 12. The contaminants 22 include, for example, at least one of a metal oxide and an organic substance. The metal oxide is an oxide formed by the reaction between the conductive film 12 and the atmosphere, which is a so-called natural oxide film.

Step S2 in this modification includes removing the contaminants 22, as illustrated in FIG. 6B. Thus, the surface of the conductive film 12 and the surface of the liner film 14 are exposed.

Step S3 in this modification includes forming the oxide film 32 by oxidizing the surface of the conductive film 12 and the surface of the liner film 14, as illustrated in FIG. 6C. Thus, in step S4 to be described later, the dense SAM 17 may be formed on both the surface of the conductive film 12 and the surface of the liner film 14.

Step S4 in this modification includes forming the SAM 17 on the surface of the conductive film 12, the surface of the barrier film 13, and the surface of the liner film 14 in a selective manner relative to the surface of the insulating film 11, as illustrated in FIG. 6D. The SAM 17 does not need to be formed on the insulating film 11.

Step S5 in this modification includes forming the target film 18 on the surface of the insulating film 11 while inhibiting the formation of the target film 18 on the surface of the conductive film 12, the surface of the barrier film 13, and the surface of the liner film 14 using the SAM 17, as illustrated in FIG. 6E. The SAM 17 inhibits the formation of the target film 18, but the blocking performance of the SAM 17 is not perfect, causing the target film 18 to protrude laterally beyond the surface of the insulating film 11.

Step S6 in this modification includes etching a portion of the target film 18 that protrudes laterally beyond the surface of the insulating film 11 by supplying a gas including H₂O to the substrate surface 1a, as illustrated in FIG. 6F. By etching the unnecessary portion of the target film 18, the wiring resistance of the substrate 1 may be reduced.

Next, the processing of the substrate 1 according to a second modification will be described with reference to FIGS. 7A to 7F. In the substrate 1 of this modification, as illustrated in FIG. 7A, the conductive film 12 is a cap film. Table 3 summarizes specific examples of the conductive film (cap film) 12, barrier film 13, liner film 14, and second conductive film 15.

TABLE 3

| Insulating | Conductive film | Barrier | Liner | Second |
|---|---|---|---|---|
| film | (Cap film) | film | film | conductive film |
| SiO film | Cu film | TaN film | Co film | Cu film |
| SiN film | Ru film | TiN film | Ru film | |
| SiOC film | | | | |
| SiON film | | | | |
| SiOCN film | | | | |

In addition, combinations of the insulating film 11, conductive film 12, barrier film 13, liner film 14 and second conductive film 15 are not particularly limited.

Steps S2 to S6 (see FIGS. 7B to 7F) of this modification are performed, similar to steps S2 to S6 (see FIGS. 6B to 6F) of the first modification.

In addition, in the embodiment, first modification, and second modification, the insulating film 11 corresponds to the first film and the conductive film 12 corresponds to the second film, but combinations of the first film and second film are not particularly limited. Table 4 summarizes candidates for combinations of the first film, second film, and target film 18 when the precursor for the SAM 17 is a thiol-based compound.

TABLE 4

| SAM | First film | Second film | Target film |
|---|---|---|---|
| Thiol-based | SiN film | Cu film | AlO film |
| | SiO film | TaN film | SiO film |
| | SiOC film | TiN film | SiN film |
| | SiON film | Co film | ZrO film |
| | SiOCN film | Ru film | HfO film |
| | Spin-on-Carbon film | Au film | |

The candidates listed in Table 4 are used in any combination. It is desirable that the first film is an insulating film, the second film is a conductive film, and the target film 18 formed on the surface of the first film is an insulating film.

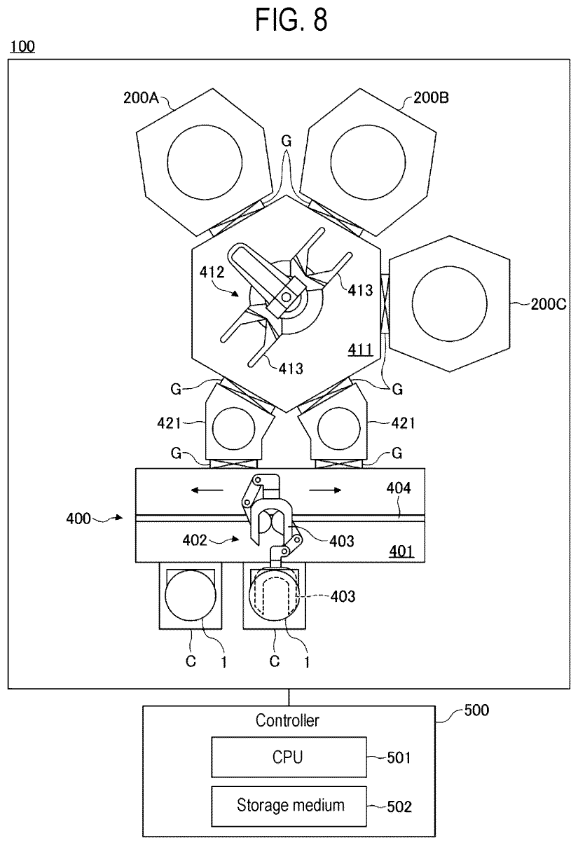

Next, a film forming apparatus 100 of performing the above film forming method will be described with reference to FIG. 8. As illustrated in FIG. 8, the film forming apparatus 100 includes a first processing section 200A, a second processing section 200B, a third processing section 200C, a transfer section 400, and a controller 500. The first processing section 200A performs steps S2 and S3 in FIG. 1. The second processing section 200B performs step S4 in FIG. 1. The third processing section 200C performs steps S5 and S6 in FIG. 1. The first processing section 200A, second processing section 200B, and third processing section 200C may have the same structure or different structures. It is also possible for only the first processing section 200A to perform all steps S2 to S6 in FIG. 1. The transfer section 400 transfers the substrate 1 to the first processing section 200A, second processing section 200B, and third processing section 200C. The controller 500 controls the first processing section 200A, second processing section 200B, third processing section 200C, and transfer section 400.

The transfer section 400 includes a first transfer chamber 401 and a first transfer mechanism 402. The internal atmosphere of the first transfer chamber 401 is an atmospheric atmosphere. The first transfer mechanism 402 is provided inside the first transfer chamber 401. The first transfer mechanism 402 includes an arm 403 that holds the substrate 1 and travels along a rail 404. The rail 404 extends in the arrangement direction of a carrier C.

Further, the transfer section 400 includes a second transfer chamber 411 and a second transfer mechanism 412. The internal atmosphere of the second transfer chamber 411 is a vacuum atmosphere. The second transfer mechanism 412 is provided inside the second transfer chamber 411. The second transfer mechanism 412 includes an arm 413 that holds the substrate 1, and the arm 413 is arranged to be movable in the vertical and horizontal directions and to be rotatable about the vertical axis. The first processing section 200A, second processing section 200B, and third processing section 200C are connected to the second transfer chamber 411 through different gate valves G.

Furthermore, the transfer section 400 includes a load lock chamber 421 between the first transfer chamber 401 and the second transfer chamber 411. The internal atmosphere of the load lock chamber 421 is switched between a vacuum atmosphere and an atmospheric atmosphere by a pressure regulating mechanism (not illustrated). Thus, the interior of the second transfer chamber 411 may always be maintained in a vacuum atmosphere. Further, the flow of gas from the first transfer chamber 401 to the second transfer chamber 411 may be prevented. Gate valves G are provided between the first transfer chamber 401 and the load lock chamber 421 and between the second transfer chamber 411 and the load lock chamber 421.

The controller 500 is, for example, a computer, and includes a central processing unit (CPU) 501 and a storage medium 502 such as a memory. The storage medium 502, which is a non-transitory computer readable storage medium, stores a program for controlling various processes executed in the film forming apparatus 100. The controller 500 controls the operation of the film forming apparatus 100 by causing the CPU 501 to execute the program stored in the storage medium 502. The controller 500 controls the first processing section 200A, second processing section 200B, third processing section 200C, and transfer section 400 to execute the film forming method.

Next, the operation of the film forming apparatus 100 will be described. First, the first transfer mechanism 402 takes out the substrate 1 from the carrier C, transfers the substrate 1 to the load lock chamber 421, and retreats from the load lock chamber 421. Subsequently, the internal atmosphere of the load lock chamber 421 is switched from an atmospheric atmosphere to a vacuum atmosphere. Thereafter, the second transfer mechanism 412 takes out the substrate 1 from the load lock chamber 421 and transfers the substrate 1 to the first processing section 200A.

Subsequently, the first processing section 200A performs steps S2 and S3. Thereafter, the second transfer mechanism 412 takes out the substrate 1 from the first processing section 200A and transfers the substrate 1 to the second processing section 200B. During this time, the atmosphere around the substrate 1 may be maintained in a vacuum atmosphere, which may prevent unintended oxidation of the substrate 1.

Subsequently, the second processing section 200B performs step S4. Thereafter, the second transfer mechanism 412 takes out the substrate 1 from the second processing section 200B and transfers the substrate 1 to the third processing section 200C. During this time, the atmosphere around the substrate 1 may be maintained in a vacuum atmosphere, thereby preventing deterioration in the blocking performance of the SAM 17.

Subsequently, the third processing section 200C performs steps S5 and S6. Next, the controller 500 checks whether steps S3 to S6 have been performed a set number of executions. If the number of executions has not reached the set number, the second transfer mechanism 412 removes the substrate 1 from the third processing section 200C and transfers the removed substrate 1 to the first processing section 200A. Thereafter, the controller 500 controls the first processing section 200A, second processing section 200B, third processing section 200C, and transfer section 400 to perform steps S3 to S6.

On the other hand, if the number of executions has reached the set number, the second transfer mechanism 412 takes out the substrate 1 from the third processing section 200C, transfers the substrate 1 to the load lock chamber 421, and retreats from the load lock chamber 421. Next, the internal atmosphere of the load lock chamber 421 is switched from a vacuum atmosphere to an atmospheric atmosphere. Thereafter, the first transfer mechanism 402 takes out the substrate 1 from the load lock chamber 421 and accommodates the substrate 1 in the carrier C. Then, the processing of the substrate is terminated.

Next, the first processing section 200A will be described with reference to FIG. 9. In addition, since the second processing section 200B and third processing section 200C are configured similar to the first processing section 200A, illustration and description thereof will be omitted.

The first processing section 200A includes a substantially cylindrical airtight processing container 210. An exhaust chamber 211 is provided in a bottom wall central portion of the processing container 210. The exhaust chamber 211 has, for example, a substantially cylindrical shape that protrudes downward. An exhaust pipe 212 is connected to the exhaust chamber 211, for example, at the lateral side of the exhaust chamber 211.

An exhaust source 272 is connected to the exhaust pipe 212 via a pressure controller 271. The pressure controller 271 includes, for example, a pressure adjustment valve such as a butterfly valve. The exhaust pipe 212 is configured to evacuate the interior of the processing container 210 using the exhaust source 272. The pressure controller 271 and exhaust source 272 constitute a gas discharge mechanism 270 that discharges gases inside the processing container 210.

A transfer port 215 is provided on the lateral side of the processing container 210. The transfer port 215 is opened or closed by a gate valve G. The loading and unloading of the substrate 1 between the interior of the processing container 210 and the second transfer chamber 411 (see FIG. 8) are achieved through the transfer port 215.

A stage 220 that is a holder for holding the substrate 1 is provided inside the processing container 210. The stage 220 holds the substrate 1 horizontally with the substrate surface 1a facing upward. The stage 220 is formed in a substantially circular shape in plan view, and is supported by a supporting member 221. A substantially circular recess 222 is formed on a surface of the stage 220 for placing the substrate 1 having a diameter of 300 mm, for example. The recess 222 has an inner diameter slightly larger than the diameter of the substrate 1. The recess 222 is configured, for example, to have substantially the same depth as the thickness of the substrate 1. The stage 220 is formed of a ceramic material such as aluminum nitride (AlN), for example. Further, the stage 220 may be formed of a metallic material such as nickel (Ni). In addition, instead of the recess 222, a guide ring for guiding the substrate 1 may be provided on the periphery of the surface of the stage 220.

The stage 220 is embedded, for example, with a grounded lower electrode 223. A heating mechanism 224 is embedded below the lower electrode 223. The heating mechanism 224 heats the substrate 1 placed on the stage 220 to a set temperature upon receiving power supplied from a power supply (not illustrated) based on a control signal from the controller 500 (see FIG. 8) In a case where the entire stage 220 is formed of a metal, the entire stage 220 functions as a lower electrode, so that it is not necessary to embed the lower electrode 223 in the stage 220. The stage 220 is provided with a plurality of (for example, three) lifting pins 231 for holding and lifting the substrate 1 placed on the stage 220. A material of the lifting pins 231 may be, for example, ceramics such as alumina (Al₂O₃) or quartz. Lower ends of the lifting pins 231 are attached to a supporting plate 232. The supporting plate 232 is connected to a lifting mechanism 234 provided outside the processing container 210 via a lifting shaft 233.

The lifting mechanism 234 is provided, for example, at the bottom of the exhaust chamber 211. A bellows 235 is provided between the lifting mechanism 234 and an opening 219 for the lifting shaft 233 formed in a lower surface of the exhaust chamber 211. The shape of the supporting plate 232 may allow that the supporting plate 232 to vertically move without interfering with the supporting member 221 of the stage 220. The lifting pins 231 are configured to vertically move between above the surface of the stage 220 and below the surface of the stage 220 by the lifting mechanism 234.

A gas supplier 240 is provided on a ceiling wall 217 of the processing container 210 via an insulating member 218. The gas supplier 240 forms an upper electrode and is opposite to the lower electrode 223. A radio frequency power supply 252 is connected to the gas supplier 240 via a matcher 251. By supplying radio frequency power in the range of 450 kHz to 100 MHz from the radio frequency power supply 252 to the upper electrode (gas supplier 240), a radio frequency electric field is created between the upper electrode (gas supplier 240) and the lower electrode 223, producing a capacitively coupled plasma. A plasma generator 250 that generates a plasma includes the matcher 251 and the radio frequency power supply 252. In addition, the plasma generator 250 is not limited to generate the capacitively coupled plasma, but may also generate other types of plasma such as inductively coupled plasma. In addition, in steps that do not generate a plasma (for example, steps S4 and S5), it is unnecessary for the gas supplier 240 to form the upper electrode, and the lower electrode 223 is also not required.

The gas supplier 240 includes a hollow gas supply chamber 241. Multiple holes 242 for dispersing and supplying a processing gas into the processing container 210 are evenly arranged, for example, on a lower surface of the gas supply chamber 241. A heating mechanism 243 is embedded above, for example, the gas supply chamber 241 in the gas supplier 240. The heating mechanism 243 is heated to a set temperature upon receiving power from a power supply (not illustrated) based on a control signal from the controller 500.

A gas supply mechanism 260 is connected to the gas supply chamber 241 through a gas supply path 261. The gas supply mechanism 260 supplies a gas used in at least one of steps S2 to S6 in FIG. 1 to the gas supply chamber 241 through the gas supply path 261. The gas supply mechanism 260 includes, although not illustrated, individual piping for each type of gas, an on/off valve provided in the middle of the individual piping, and a flow-rate controller provided in the middle of the individual piping. When the shutoff valve opens the individual piping, the gas is supplied from a supply source to the gas supply path 261. The supply amount of gas is controlled by the flow-rate controller. On the other hand, when the on/off valve closes the individual piping, the supply of gas from the supply source to the gas supply path 261 is stopped.

### EXAMPLES

Next, examples will be described. The following Example 1-1 is an example, and Example 1-2 is a comparative example. Examples 2-1 to 2-3 are reference examples.

### Example 1-1

In Example 1-1, the substrate 1 illustrated in FIG. 2A was prepared. The base substrate 10 was a silicon wafer, the insulating film 11 was an SiOC film, the conductive film 12 was a Cu film, and the barrier film 13 was a TaN film. In the surface of the SiOC film, a trench width was 20 nm, and a trench pitch was 40 nm.

In Example 1-1, steps S1 to S7 illustrated in FIG. 1 were performed. In step S2, a plasmarized cleaning gas was supplied to the substrate surface 1a. The cleaning gas contained an H₂ gas, N₂ gas, and Ar gas. In step S3, an O₂ gas was supplied as an oxygen-containing gas to the substrate surface 1a.

In step S4, steps S41 to S43 illustrated in FIG. 3 were performed to form the SAM 17. An O₂ gas was used as an oxygen-containing gas, and a PFOT gas was used as an organic compound gas. The set number of executions for step S43, i.e., the number of repetitions of steps S41 and S42 was 5.

In step S5, steps S51 to S55 illustrated in FIG. 4 were performed to form an SiO film as the target film 18. In addition, in step S51, instead of an Al-containing gas, an Si-containing gas (specifically, tris(tert-pentoxy)silanol: TPSOL ((CH₃CH₂C(CH₃)₂O)₃SiOH) gas) was used. In step S53, instead of an oxidation gas, TMA ((CH₃)₃Al) gas was used. The TMA gas in step S53 acted as a catalyst that promoted the dehydration condensation reaction of TPSOL, forming an SiO film. The set number of executions for step S55, i.e., the number of repetitions of steps S51 to S54 was 1. The thickness of the SiO film was 3 nm.

In step S6, steps S61 to S63 illustrated in FIG. 5 were performed to etch the unnecessary portion of the target film 18. In step S62, a plasmarized H₂ gas was used. The set number of executions for step S63, i.e., the number of repetitions of steps S61 to S63 was 3.

The set number of executions for step S7, i.e., the number of repetitions of steps S3 to S6 was 4. After that, the results of observing SEM images of the substrate cross section showed that at least part of the surface of the Cu film, which is the conductive film 12, was exposed and was not covered with the SiO film, which is the target film 18.

### Example 1-2

In Example 1-2, the same substrate processing condition as in Example 1-1 was used except that step S41 (supply of oxygen-containing gas) illustrated in FIG. 3 was not performed, and only step S42 (supply of organic compound gas) was repeated five times. After that, the results of observing SEM images of the substrate cross section showed that the entire surface of the Cu film, which is the conductive film 12, was covered with the SiO film, which is the target film 18.

### Examples 2-1 to 2-3

In Examples 2-1 to 2-3, only step S2 (removal of contaminants) was performed on the silicon wafer. Table 5 lists the cleaning gas used in step S2. The cleaning gas was plasmarized. The silicon wafer used was a bare wafer.

TABLE 5

| | Example 2-1 | Example 2-2 | Example 2-3 |
|---|---|---|---|
| Ar [vol %] | 7 | 3 | 13 |
| H₂ [vol %] | 47 | 19 | 87 |
| N₂ [vol %] | 47 | 78 | 0 |

In Examples 2-1 and 2-2, the cleaning gas contained an H₂ gas and N₂ gas, whereas in Example 2-3, the cleaning gas contained an H₂ gas only without an N₂ gas.

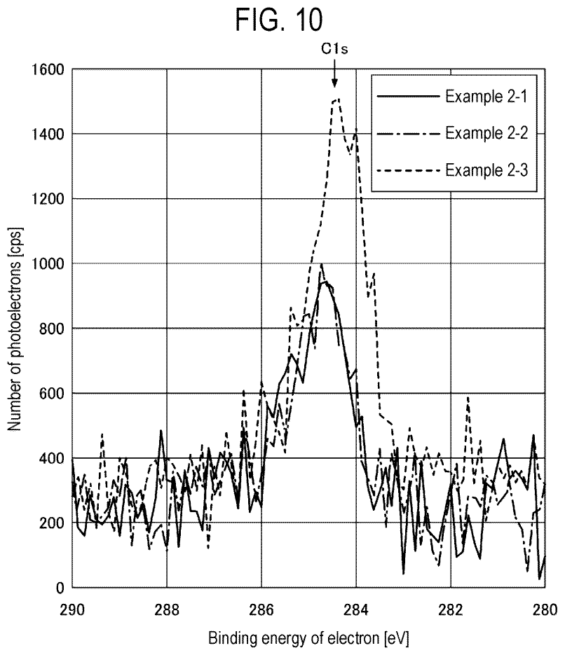

FIG. 10 illustrates the XPS spectra of the substrate surfaces obtained in Examples 2-1 to 2-3. As evident from FIG. 10, it can be seen that when the cleaning gas contained an N₂ gas in addition to an H₂ gas, the carbon (C) peak was smaller and the removal efficiency of organic substances was higher, compared to a case where the cleaning gas contained only H₂ gas without an N₂ gas.

According to one aspect of the present disclosure, it is possible to enhance the density of a self-assembled monolayer.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

This application claims priority based on Japanese Patent Application No. 2022-153617 filed on Sep. 27, 2022 to the Japan Patent Office, and the entirety of Japanese Patent Application No. 2022-153617 is incorporated in this application.

What is claimed is:

1. A film forming method comprising:
preparing a substrate having a first film and a second film on different regions of a surface of the substrate, the second film being formed of a material different from that of the first film; and
forming a self-assembled monolayer on a surface of the second film in a selective manner relative to a surface of the first film by supplying an organic compound gas and an oxygen-containing gas that does not contain an OH group into a processing container accommodating the substrate.

2. The film forming method of claim 1, further comprising forming an oxide film by oxidizing the surface of the second film, before the forming the self-assembled monolayer.

3. The film forming method of claim 2, further comprising removing a contaminant from the surface of the substrate, before the forming the oxide film.

4. The film forming method of claim 3, wherein the removing the contaminant includes supplying a plasmarized cleaning gas to the surface of the substrate, and
wherein the cleaning gas includes a hydrogen gas and a nitrogen gas.

5. The film forming method of claim 4, wherein the first film is an insulating film, and the second film is a conductive film.

6. The film forming method of claim 1, wherein the forming the self-assembled monolayer includes alternately and repeatedly supplying the organic compound gas and the oxygen-containing gas that does not contain an OH group into the processing container.

7. The film forming method of claim 1, wherein the organic compound gas includes a thiol-based compound.

8. The film forming method of claim 1, wherein the oxygen-containing gas that does not contain an OH group includes at least one selected from an O₂ gas, O₃ gas, NO gas, NO₂ gas, and N₂O gas.

9. The film forming method of claim 1, comprising forming a target film on the surface of the first film while inhibiting formation of the target film on the surface of the second film using the self-assembled monolayer.

10. The film forming method of claim 9, further comprising etching a portion of the target film that protrudes laterally beyond the first film, after the forming the target film.

11. The film forming method of claim 10, wherein the organic compound gas contains fluorine, and
wherein the etching the portion of the target film includes supplying an H₂O-containing gas to the surface of the substrate.

12. The film forming method of claim 11, wherein the etching the portion of the target film includes supplying both the H₂O-containing gas and the plasmarized gas to the surface of the substrate.

13. The film forming method of claim 10, wherein the forming the self-assembled monolayer, the forming the target film, and the etching the portion of the target film are repeated a plurality of times in this order.

14. A film forming apparatus comprising:
the processing container;
a holder configured to hold the substrate in an interior of the processing container;
a gas supply mechanism configured to supply a gas to the interior of the processing container;
a gas discharge mechanism configured to discharge the gas from the interior of the processing container;
a transfer mechanism configured to load or unload the substrate into or from the processing container; and
a controller configured to control the gas supply mechanism, the gas discharge mechanism, and the transfer mechanism to perform the film forming method of claim 1.

15. The film forming method of claim 1, wherein the first film is an insulating film, and the second film is a conductive film.
